(19) United States
(12) Patent Application Publication
(10) Pub. No.: US 2026/0241420 A1
(43) Pub. Date: Aug. 20, 2026

(54) BRUSH NODULE WITH RIBBED SURFACE

(71) Applicant: TCNV, LLC, Minden, NV (US)

(72) Inventors: Briant Benson, Placerville, CA (US); Michael Dobbins, Citrus Heights, CA (US); Maxim Nesmiyan, Antelope, CA (US); David Ottman, Carmichael, CA (US); William Shortridge, Fair Oaks, CA (US)

(21) Appl. No.: 19/544,295

(22) Filed: Feb. 19, 2026

Related U.S. Application Data
(60) Provisional application No. 63/760,598, filed on Feb. 19, 2025.

(51) Int. Cl. B08B 1/12; A46B 9/00; H10P 70/00; H10P 72/00

(52) U.S. Cl. CPC B08B 1/12; A46B 9/005; H10P 70/15; H10P 72/0412; A46B 2200/30

(57) ABSTRACT

Textured polyvinyl alcohol (PVA) brush nodules and brush assemblies are disclosed for wet cleaning of sensitive substrates such as semiconductor wafers. A cylindrical brush includes a core configured for rotation and a plurality of PVA nodules disposed on the core. Each nodule has a nodule face including molded-in surface geometry (e.g., ridges and grooves) configured to disrupt and redistribute liquid at a brush/substrate interface, promote interface shear, and reduce hydroplaning-like fluid lift to help maintain contact under wet conditions. In certain embodiments, a fluid management arrangement directs cleaning liquid toward the nodule faces so that liquid exits predominantly at or through the nodule faces, improving purging and reducing water and chemistry consumption. Modular rail embodiments and manufacturing methods, including planar tray molds with CNC-machined cavity face surface geometry for forming textured nodule faces, are also described.

### BACKGROUND FOR THE DISCLOSURE

### PRIORITY INFORMATION

The present application claims priority to United States Provisional Patent Application No. 63/760,598, filed February 19, 2025, the contents of which are incorporated herein as if set out in full.

### TECHNICAL FIELD OF THE DISCLOSURE

The present disclosure relates to precision cleaning tools and to methods and tooling for manufacturing such tools. More particularly, the present disclosure relates to cylindrical scrubbing brushes having a plurality of protrusions or “nodules” formed of a polymeric material (for example, polyvinyl alcohol (PVA) or other porous, compliant materials) and used in wet cleaning operations to remove particulates, residues, and other contaminants from substrates. In representative embodiments, such substrates include semiconductor wafers and other high-value workpieces processed in microelectronics, optoelectronics, flat-panel display, and optical fabrication environments.

The present disclosure further relates to molds, mold components, and molding processes used to form nodules and, in particular, to processes that enable formation of defined surface geometries on nodule faces. The disclosure also relates to brush assemblies and brush modules (including modular rail-based brush constructions) that cooperate with such molded nodule geometries and with liquid delivery during scrubbing.

### BACKGROUND AND DESCRIPTION OF THE RELATED ART

In a variety of precision manufacturing environments, workpieces may be subjected to processes that generate or deposit fine particulates and residues on a surface of the workpiece. By way of non-limiting example, chemical-mechanical planarization (CMP) of semiconductor wafers can generate slurry particles and reaction byproducts that are desirably removed in post-process wet cleaning steps. In such contexts, cleaning performance can directly impact yield, reliability, and downstream process stability.

Cylindrical scrubbing brushes formed of compliant, porous polymeric materials (including PVA-based materials) are widely used in wet scrubbing tools for removing particles and residues. In typical operation, a brush rotates relative to a substrate surface while a cleaning liquid (for example, deionized (DI) water and/or a chemical cleaning composition) is supplied at the brush/substrate interface. Removal efficacy may be influenced by a combination of mechanical action (contact pressure, relative motion, and local shear) and fluid action (wetting, transport, and flushing of dislodged material).

In practice, however, cleaning systems based on compliant porous brushes can exhibit non-ideal behaviors that reduce cleaning uniformity and/or increase resource consumption. For example, the effective contact area between nodules and a substrate surface may vary across the substrate due to tool tolerances, brush wear, deformation of compliant materials, substrate topography, and/or brush-to-substrate alignment (including angled application). Variations in contact pressure and contact area can create regions of over-scrubbing and regions of under-scrubbing, each of which can be undesirable for defectivity and uniformity.

Fluid behavior at the brush/substrate interface can further influence cleaning results. Under wet, high-speed scrubbing conditions, a fluid film may develop between the brush and the substrate. Depending on process parameters (e.g., speed, compression, and liquid supply), the fluid film can reduce effective mechanical engagement in some regions and can contribute to nonuniform particle removal. In addition, dislodged contaminants may be transported by the liquid and can be susceptible to redeposition or cross-contamination if not efficiently flushed away from the interface.

Brush nodule geometry can significantly affect both mechanical engagement and local fluid transport at the interface. In many brush designs, nodules are formed with a generally flat or smoothly curved face and a perimeter edge transition. Such geometries may not maintain consistent engagement under all wet operating conditions, and can contribute to localized gaps, nonuniform pressure distribution, and/or nonuniform flushing. In addition, conventional approaches may have limited flexibility to tailor nodule-face surface geometry to influence wet traction, liquid distribution, or contaminant egress at the interface.

Manufacturing constraints can also limit the ability to implement and reproducibly produce advanced nodule-face geometries. For example, some brush manufacturing processes form a brush body and nodules using tubular forms or sleeve-based molds (for example, molds having a generally cylindrical/pipe-like cavity), and then bond or secure the molded brush body to a core. Depending on the process, the nodule-forming cavity surfaces may have restricted access for machining and finishing operations, which can constrain the practical complexity and fidelity of features that can be formed on the nodule faces. As a result, attempts to introduce fine, repeatable surface geometry onto a nodule face may be limited by tooling access, process variability, and/or demolding considerations.

Accordingly, there remains a need for cleaning brush systems and manufacturing approaches that enable precise and repeatable formation of nodule-face surface geometry, while maintaining compatibility with wet cleaning chemistries and high-throughput operation. There is further a need for brush assemblies and liquid delivery approaches that cooperate with such nodule-face surface geometry to promote effective contaminant removal, reduce redeposition risk, and improve liquid usage efficiency.

The foregoing background is provided to assist understanding of the technology and the context of the disclosure. It is not intended, and should not be construed, as an admission that any feature described herein constitutes prior art with respect to any claim or embodiment.

### SUMMARY OF THE DISCLOSURE

The present disclosure provides, among other things, manufacturing tooling and processes that enable repeatable production of cleaning brush nodules having defined surface geometry on a nodule face, and brush assemblies incorporating such nodules for wet precision cleaning. In representative embodiments, the manufacturing approach is treated as an enabling backbone because it permits defined nodule-face surface geometries to be formed with fidelity and repeatability, which in turn supports improved interface behavior during wet scrubbing.

In one aspect, a mold apparatus is provided. The mold apparatus may include a generally planar mold tray or mold plate (e.g., a flat tray) defining an array of nodule-forming cavities. In representative embodiments, the cavities are open at, or accessible from, a major surface of the tray. Each cavity may include a cavity face surface geometry that corresponds (as a negative) to a desired surface geometry on a face of a molded nodule. The cavity face surface geometry may be formed, for example, by computer numerical control (CNC) machining, milling, engraving, or other machining operations performed on the mold tray/plate. Because the cavity face is accessible in a generally planar/tray configuration, the cavity face surface geometry may be produced with higher freedom of design than would be practically achievable with certain restricted-access tubular molding approaches. In some embodiments, the cavity face surface geometry defines a plurality of ribs/ridges and intervening grooves/valleys configured to form a ribbed (ridged) nodule face.

In another aspect, a method of forming a plurality of nodules is provided. The method may include providing a mold apparatus including a generally planar mold tray/plate defining an array of nodule-forming cavities, and introducing a nodule-forming material into the cavities. In representative embodiments, the nodules are molded such that the nodule faces are formed against the cavity face surface geometries (i.e., face-down molding). The method may further include curing, setting, or otherwise forming the material to define a nodule body and a nodule face, and demolding the nodules from the tray/plate. In some embodiments, the method includes forming nodules from polyvinyl alcohol (PVA) or other compliant polymeric materials suitable for wet scrubbing. In some embodiments, the method further includes post-processing steps (e.g., rinsing, conditioning, trimming) and/or assembly steps for incorporating the nodules into a brush assembly.

In another aspect, a cleaning brush assembly is provided. The brush assembly may include a plurality of nodules, each nodule including a nodule face defining a surface geometry. In representative embodiments, the surface geometry includes a plurality of ridges and grooves. The ridges may be configured to improve wet-interface engagement and to influence liquid transport at a brush/substrate interface during scrubbing. In some embodiments, the ridges define channels and/or micro-scale pathways that facilitate distribution of cleaning liquid and egress of dislodged particles from the interface.

In some embodiments, the nodule face includes an edge treatment at a perimeter of the nodule face. The edge treatment may include, for example, a radius, fillet, chamfer, or blended transition between the nodule face and an adjacent nodule sidewall or perimeter region. Such edge treatment may be configured to reduce localized gaps and/or to promote more uniform contact behavior at the interface.

In some embodiments, the brush assembly is modular. For example, a brush assembly may include a core and one or more modules (e.g., rail modules) that carry and position the nodules relative to the core. A rail module may include a rail body defining a plurality of nodule receptacles and may be configured to mount to, or around, the core. In such embodiments, modularity may facilitate manufacture, servicing, and/or replacement of nodules or groups of nodules, and may facilitate implementation of different nodule patterns or geometries in different regions of a brush.

In some embodiments, the brush assembly and/or modules cooperate with a liquid delivery arrangement. For example, cleaning liquid may be delivered through or along a core and distributed to the nodules or to an interface between the nodules and a substrate. In some embodiments, structural features and/or materials are arranged to encourage a substantial portion of supplied liquid to exit in proximity to, and/or through, nodule faces. Such arrangements can, in some implementations, improve liquid usage efficiency while maintaining or improving particle removal performance. Other liquid delivery arrangements are also contemplated.

The disclosed concepts may be implemented with a wide range of nodule-face surface geometries. By way of non-limiting example, ridges may be substantially linear, curved, angled, or sinusoidal; may be oriented perpendicular to, parallel to, or at an angle relative to a direction of relative motion; and may have various cross-sectional profiles (e.g., rounded, trapezoidal, or other profiles). Ridges may be continuous or discontinuous, and may be arranged in patterns (e.g., chevron or herringbone patterns) or in other arrangements. Ridge pitch, ridge height, ridge count per nodule, and other geometry parameters may be selected based on intended substrates, process conditions, and desired interface behavior.

The disclosed concepts may also be implemented with different nodule sizes, nodule layouts, and nodule distributions. For example, nodules may be arranged in rows and columns, staggered arrangements, or other patterns around a brush. In some embodiments, nodules may have varying heights and/or face geometries in different regions of a brush to accommodate different scrubbing angles or to tune local contact behavior.

The foregoing summary is provided to introduce a selection of concepts in a simplified form that are further described in the detailed description. The summary is not intended to identify essential features of the claimed subject matter, nor is it intended to be used to limit the scope of any claim. Additional features and advantages will become apparent from the following description and the accompanying drawings.

### BRIEF DESCRIPTION OF THE DRAWINGS

Elements in the figures have not necessarily been drawn to scale in order to enhance their clarity and improve understanding of these various elements and embodiments of the disclosure. Furthermore, elements that are known to be common and well understood to those in the industry are not depicted in order to provide a clear view of the various embodiments of the disclosure. Thus, the drawings are generalized in form in the interest of clarity and conciseness.

FIG. 1 is a perspective view of an example nodule 130 including a nodule face 134 having a plurality of ridges 136 and grooves 138, and an edge-treated perimeter region (140).

FIG. 2 is a perspective view illustrating a nodule 130 in relation to a mold tray 200 and a nodule-forming cavity 210, for example as part of a face-down molding approach that enables formation of nodule-face surface geometry.

FIG. 3 is a side view of an example nodule 130 having a nodule face 134 defining raised ridges 136 separated by grooves 138, and an edge treatment 140 at a perimeter of the nodule face.

FIG. 4 is a cross-sectional view of the nodule 130 of FIG. 3, illustrating an example ridge/groove profile at the nodule face 134.

FIG. 5 is a schematic view illustrating a plurality of nodules 130 engaging a substrate (10) at a first example offset (e.g., 0.25 mm), and illustrating a contact region 32 at a substrate surface (12).

FIG. 6 is a schematic view illustrating a plurality of nodules 130 engaging a substrate (10) at a second example offset (e.g., 1.00 mm), and illustrating a contact region 32 at a substrate surface 12.

FIG. 7 is a schematic view illustrating a plurality of nodules 130 engaging a substrate (10) at a third example offset (e.g., 1.75 mm), and illustrating a contact region 32 at a substrate surface 12.

FIG. 8A is a schematic view illustrating an example interaction of a particle/contaminant 14 with fluid 16 flow adjacent a substrate surface 12 of a substrate 10, for example illustrating a baseline interaction at a wet cleaning interface.

FIG. 8B is a schematic view illustrating an example interaction between a nodule 130, fluid 16, and a particle/contaminant 14 adjacent a substrate surface 12 of a substrate 10.

FIG. 9A is a schematic view illustrating an example brush/nodule contact configuration in which a nodule 130 engages a substrate 10 at a substrate surface 12 and a localized contact gap 30 and contact region 32 may form, including an edge-treated nodule configuration 140; arrow 150 indicates an example direction of brush surface motion at the interface and arrow 152 indicates an example direction of relative motion of the substrate.

FIG. 9B is an example contact area image illustrating an example contact gap 30 and contact region 32 associated with a standard nodule.

FIG. 9C is an example contact area image illustrating an example contact region 32 associated with an edge-treated nodule.

FIG. 10 is a perspective view of an example nodule 130 having a nodule face 134 with a sinusoidal ridge/groove surface geometry defined by ridges 136 and grooves 138, and an edge treatment 140.

FIG. 11 is a perspective view of an example rail module 120 having a rail body 122 defining a plurality of nodule receptacles 124, one or more side openings 126, and one or more passageways/ports 128.

FIG. 12A is a top view of the rail module 120 illustrating example nodule receptacles 124.

FIG. 12B is a side/cross-sectional view of the rail module 120 illustrating the rail body 122, example passageways/ports 128, and an end feature 129.

FIG. 13 is a perspective view of an example brush assembly 100 including a core (110), an end fitting 112, one or more rail modules 120, and a plurality of nodules 130

FIG. 14 is a partial top view of an example flat mold tray 200 including an upper surface 202, alignment features 204, and an array 206 of nodule-forming cavities 210, together with a detail view illustrating a nodule 220 formed face-down in a cavity and a cavity face surface geometry 214 configured (e.g., via CNC machining) to form surface geometry on the nodule face region 222.

### DETAILED DESCRIPTION OF THE DRAWINGS

In the following discussion that addresses a number of embodiments and applications of the present disclosure, reference is made to the accompanying drawings that form a part hereof, and in which is shown by way of illustration specific embodiments in which the disclosure may be practiced. It is to be understood that other embodiments may be utilized, and changes may be made without departing from the scope of the present disclosure.

Various inventive features are described below that can each be used independently of one another or in combination with other features. However, any single inventive feature may not address any of the problems discussed above or only address one of the problems discussed above. Further, one or more of the problems discussed above may not be fully addressed by any of the features described below.

As used herein, the singular forms "a", "an" and "the" include plural referents unless the context clearly dictates otherwise. As used herein, "or" is inclusive unless the context clearly indicates otherwise. As used herein, "and/or" is intended to mean any one or more of the associated listed items, individually or in combination. All embodiments of any aspect of the disclosure can be used in combination, unless the context clearly dictates otherwise.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “wherein”, “whereas” “above,” and “below” and words of similar import, when used in this application, shall refer to this application as a whole and not to any particular portions of the application.

The description of embodiments of the disclosure is not intended to be exhaustive or to limit the disclosure to the precise form disclosed. While the specific embodiments of, and examples for, the disclosure are described herein for illustrative purposes, various equivalent modifications are possible within the scope of the disclosure, as those skilled in the relevant art will recognize.

In general, the present disclosure relates to wafer-cleaning brushes configured to dispense one or more cleaning fluids through an array of nodules. In use, the cleaning fluid may include deionized (DI) water, a chemical cleaning agent, or a mixture thereof. The brush may be used, for example, in post-chemical mechanical planarization (post-CMP) cleaning and other wet cleaning operations in which controlled delivery of fluid at a brush-wafer interface is desired.

### Mold apparatus enabling defined nodule-face surface geometry

In some embodiments, the disclosed nodule-face surface geometries (including ribbed or ridged geometries) are enabled by a mold apparatus configured to provide manufacturing access to a cavity surface that forms a nodule face. By enabling such access, the mold apparatus permits formation of a wide range of nodule-face surface geometries with improved design freedom and repeatability, including surface geometries that may be difficult to implement using restricted-access molding configurations.

Referring to FIG. 14, an example mold apparatus may include a mold tray or mold plate 200. In representative embodiments, the mold tray 200 is generally planar (i.e., a flat tray), and defines an upper surface 202 from which an array 206 of nodule-forming cavities 210 is accessible. In some embodiments, the mold tray 200 further includes one or more alignment features 204 (e.g., holes, pins, keyways, or registration features) to establish repeatable alignment with a mating part, cover plate, or handling fixture.

In representative embodiments, each cavity 210 defines (or includes) a cavity face surface geometry 214. The cavity face surface geometry 214 corresponds (as a negative) to a desired surface geometry on a nodule face region 222 of a molded nodule 220. Stated differently, the surface geometry present on the nodule face region 222 is formed as a replica of the cavity face surface geometry 214 (subject to expected molding tolerances, shrinkage/swelling, and material behavior). In some embodiments, the nodule face region 222 corresponds to the nodule face 134 of a nodule 130 in use.

In some embodiments, the cavity face surface geometry 214 is formed by machining the mold tray 200 (or an insert portion thereof) using computer numerical control (CNC) machining, milling, engraving, or similar subtractive operations. The planar/flat configuration of the mold tray 200 provides direct access to the cavity face surface geometry 214, which can allow a tool path to be executed with reduced geometric constraint relative to approaches where a cavity face is recessed within a narrow tubular volume. In some embodiments, the cavity face surface geometry 214 is formed by electrical discharge machining (EDM), laser machining, chemical etching, additive fabrication of an insert, or combinations thereof.

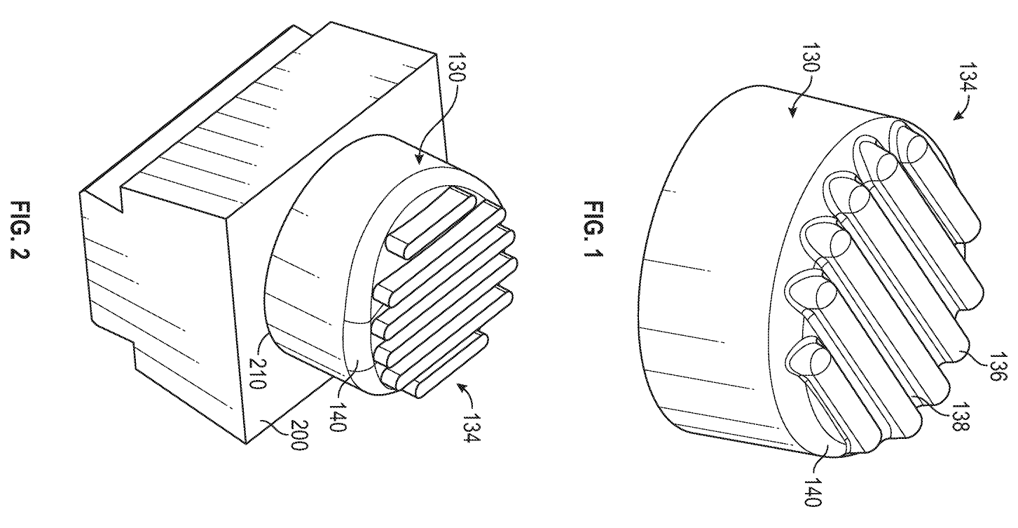

The cavity face surface geometry 214 may include a plurality of protrusions and recesses configured to form surface features on the molded nodule 220. For example, the cavity face surface geometry 214 may define a plurality of ridge-forming features and valley-forming features configured to mold a nodule face 134 having a plurality of ridges (136) separated by grooves (138) (see, e.g., FIGS. 1, 3, 4, and 10). The cavity face surface geometry 214 may also define a perimeter transition configured to form an edge treatment 140 (e.g., a radius, chamfer, fillet, or blended transition) at a perimeter of the nodule face.

In some embodiments, the mold tray 200 is fabricated from a material selected for machinability, dimensional stability, and compatibility with the nodule forming material. Non-limiting examples include engineering polymers (e.g., acetal), aluminum alloys, stainless steels, and composite materials. In some embodiments, the cavity face surface geometry 214 is formed in removable inserts that are mounted to a base tray/plate, allowing inserts to be changed to implement different nodule-face surface geometries without replacing the entire mold tray.

In some embodiments, the cavities 210 are arranged in rows and columns (array 206) corresponding to a desired production layout and/or to a desired downstream assembly format. For example, cavities 210 may be arranged such that a plurality of nodules may later be assembled into modular components (e.g., rail modules) or other brush subassemblies. Other cavity arrangements, including staggered patterns or non-uniform distributions, are also contemplated.

### Face-down molding of nodules and formation of textured nodule faces

In some embodiments, nodules are formed by introducing a nodule-forming material into the cavities 210 and forming (e.g., curing/setting) the material such that the nodule face region 222 is formed against the cavity face surface geometry 214. This may be referred to herein as “face-down” molding, meaning that the surface of the nodule intended to contact a substrate during cleaning (i.e., the nodule face) is molded against, and defined by, a corresponding cavity face surface geometry.

In representative embodiments, the nodule-forming material includes polyvinyl alcohol (PVA) or other compliant polymeric materials suitable for wet scrubbing. In some embodiments, the nodule-forming material is a precursor mixture that, after forming and post-processing, yields a porous, compliant structure. For example, a precursor mixture may include one or more porogens (e.g., a soluble particulate) that are later removed (e.g., by washing/leaching) to yield a porous structure. Material compositions and processing conditions may be selected based on target porosity, compliance, chemical compatibility, and abrasion resistance.

In some embodiments, the nodule-forming material is introduced into cavities 210 by pouring, dispensing, casting, injection, or other filling techniques. In some embodiments, a cover plate, carrier film, or mating mold portion is positioned relative to the mold tray 200 (e.g., using alignment features 204) to define one or more sidewall regions of the nodules and/or to define a common support region for a plurality of nodules.

In some embodiments, a void-management process is used to reduce trapped air in the molded features. Non-limiting examples include vacuum degassing of a precursor material prior to filling, applying vacuum during or after filling, and/or mechanically agitating the mold tray 200 after filling. In some embodiments, the mold tray 200 is positioned on a vibration table to encourage air bubbles to detach from mold surfaces and migrate away from the cavity face surface geometry 214.

Advantageously, in face-down molding implementations, air bubbles can have a tendency to migrate upward (away from the cavity face surface geometry 214) due to buoyancy, which can reduce the likelihood of bubble-induced defects at the nodule face region 222. In some embodiments, the vibration-assisted process described above further reduces bubble adhesion at the cavity face and improves replication fidelity of the cavity face surface geometry 214 at the molded nodule face region 222.

After forming, the nodules 220 may be demolded from the mold tray 200. In some embodiments, cavity surfaces include draft angles and/or are configured to avoid undercuts that would impede demolding, while still allowing replication of the desired nodule-face surface geometry. In some embodiments, release agents and/or surface treatments are applied to mold surfaces to facilitate demolding and preserve feature fidelity.

In some embodiments, post-processing steps are performed after demolding. Non-limiting examples include washing/leaching to remove porogens, rinsing, conditioning, trimming, and dimensional stabilization steps. In some embodiments, post-processing is selected to preserve the geometry of ridges (136), grooves (138), and edge treatment features (140) on the nodule face.

### Design freedom enabled by planar mold access

The disclosed mold tray approach can enable a broad range of nodule-face surface geometries. Non-limiting examples include substantially linear ridges, curved ridges, angled ridges, and sinusoidal or wave-like ridges (see, e.g., FIG. 10). Cross-sectional profiles may be rounded, trapezoidal, or other profiles. Features may be continuous or discontinuous, and may be arranged in patterns (e.g., chevron or herringbone patterns) or other arrangements. Ridge height, ridge pitch, ridge spacing, ridge count per nodule, and edge-treatment parameters may be selected based on the intended substrate and process conditions.

In some embodiments, the cavity face surface geometry 214 is configured to form an edge treatment 140 that is integral with the nodule-face surface geometry. For example, the cavity face surface geometry may transition smoothly at a perimeter to form a rounded perimeter transition at the nodule face. Such integral formation can reduce or eliminate the need for secondary finishing operations at the nodule face (e.g., mechanical grinding) and can improve repeatability from nodule to nodule.

In some embodiments, the planar mold access provided by the mold tray 200 also facilitates rapid iteration of nodule-face surface geometries during development and production. For example, different inserts having different cavity face surface geometries may be swapped into a base tray, or different trays may be used in parallel, allowing evaluation of multiple nodule-face surface geometries under controlled conditions.

### Integration with downstream brush structures

The nodules formed using the mold tray 200 may be incorporated into a brush assembly in a variety of ways. In some embodiments, nodules are formed as discrete elements and then mounted to a carrier, module, or brush body. In other embodiments, multiple nodules may be formed integrally with a support portion (e.g., a strip or bar) that facilitates subsequent assembly into a modular brush construction. In still other embodiments, nodules may be formed directly into, or onto, a structural component via overmolding or insert molding techniques.

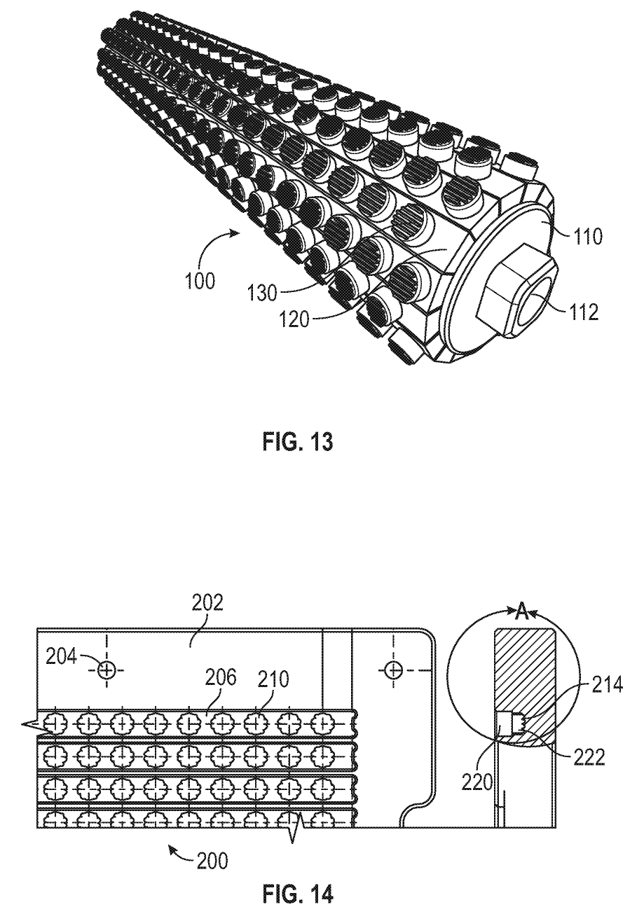

By way of non-limiting example, FIG. 13 illustrates a brush assembly 100 including a core 110 and one or more modules (e.g., rail modules 120) carrying nodules 130. Although rail modules and brush assembly details are described in greater detail in subsequent sections, the manufacturing concepts described herein be used to form nodule-face surface geometries for nodules that are later assembled into such modular structures.

The foregoing description of mold apparatus and methods is provided by way of example. Additional embodiments and variations will be apparent to those skilled in the art in view of this disclosure. The scope of the disclosure is defined by the claims.

### Overview of nodules and nodule-face surface geometry

The disclosed brush assemblies may include a plurality of nodules 130. In representative embodiments, each nodule 130 includes a nodule face 134 configured to contact a substrate during a wet scrubbing operation. The nodule face 134 may define a surface geometry configured to influence mechanical engagement and liquid transport at a brush/substrate interface.

In some embodiments, the nodule face 134 is non-planar due to defined surface features formed on the face. For example, the nodule face 134 may include a plurality of ridges 136 separated by grooves 138 (see, e.g., FIGS. 1, 3, and 4). In some embodiments, the ridges 136 and grooves 138 define a textured surface geometry that provides multiple discrete contact features and/or channels at the interface. In some embodiments, the ridges 136 are formed as raised features on the nodule face 134; in other embodiments, a functionally similar geometry may be implemented by recessing grooves or channels into the nodule face 134, or by combinations thereof.

The surface geometry on the nodule face 134 may be formed integrally during molding, for example via the cavity face surface geometry 214 described in connection with FIG. 14. In such embodiments, the ability to machine the cavity face surface geometry 214 (e.g., by CNC machining) can enable repeatable formation of ridges 136, grooves 138, and edge-treatment features 140 with improved design flexibility.

### Ridge and groove configurations

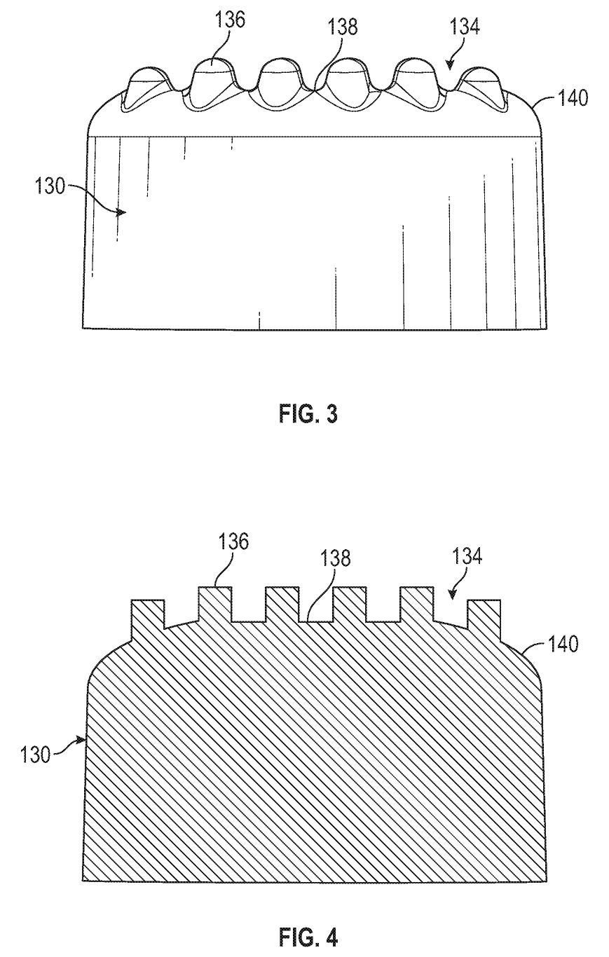

In some embodiments, the ridges 136 are substantially linear and extend generally laterally across the nodule face 134 (for example, across a width of the nodule face) as depicted schematically in FIGS. 1 and 3. In such embodiments, the grooves 138 between adjacent ridges 136 can define channel-like regions that facilitate liquid distribution and particle egress during scrubbing.

In some embodiments, the ridges 136 and grooves 138 have a sinusoidal or wave-like configuration, as illustrated in FIG. 10. In some embodiments, wave-like ridges can provide multiple changes in local ridge orientation across the face, which can influence the direction and distribution of liquid transport at the interface.

In some embodiments, the ridges 136 may have various cross-sectional profiles. By way of non-limiting example, ridge peaks may be rounded, flattened, or otherwise shaped, and groove bottoms may be rounded or flattened. FIG. 4 illustrates an example cross-sectional profile for a ridged nodule face 134. In some embodiments, selection of ridge and groove profiles is used to tune contact stress distribution, durability, and replication fidelity during molding.

In some embodiments, ridge geometry and/or orientation may be selected to influence anisotropic traction at the interface. For example, ridges 136 may be oriented substantially perpendicular to a direction of relative motion (e.g., relative motion driven by brush rotation) to increase wet traction and reduce slip under certain conditions. In other embodiments, ridges 136 may be oriented at a skew angle relative to a direction of relative motion to impart directional transport of liquid and/or dislodged contaminants. Such angled-ridge embodiments can be formed by corresponding angled features in the cavity face surface geometry 214.

In some embodiments, ridge patterns are selected from a set of candidate patterns including, without limitation, substantially parallel ridges, cross-hatched patterns, chevron patterns, and herringbone patterns. In some embodiments, ridge patterns are selected to promote fluid mixing and flushing at the interface, to reduce the likelihood of localized fluid-film lift, and/or to reduce redeposition of dislodged contaminants. Unless explicitly stated, such functional descriptions are not intended to be limiting and are provided as representative objectives.

### Edge treatment at the nodule-face perimeter

In some embodiments, a nodule 130 includes an edge treatment 140 at a perimeter of the nodule face 134. The edge treatment 140 may include a radius, fillet, chamfer, bevel, or blended transition between the nodule face 134 and an adjacent perimeter region. In some embodiments, the edge treatment 140 is formed integrally during molding (e.g., as part of cavity face surface geometry 214), thereby providing repeatable perimeter geometry and reducing or eliminating secondary finishing operations.

In some embodiments, the edge treatment 140 is configured to reduce formation of localized contact gaps and/or to reduce localized stress concentrations at the nodule-face perimeter. In some embodiments, the edge treatment 140 promotes a smoother transition of deformation as the nodule 130 is compressed against a substrate during scrubbing.

In some embodiments, edges of surface features on the nodule face 134 are also rounded. For example, ridge peaks and groove transitions may be formed with small radii rather than sharp corners. Such radiusing can improve replication fidelity during molding, reduce the likelihood of tearing during demolding, and improve durability during use. In some embodiments, the nodule is formed such that substantially all external transitions at the nodule face 134 are radiused rather than square.

In some non-limiting examples, a radius used for the edge treatment 140 (and/or for feature-edge radiusing on ridges 136) may be selected within a range from about 0.35 mm to about 0.85 mm. In other embodiments, smaller or larger radii may be used depending on nodule size, ridge geometry, and molding constraints. The foregoing numeric example is not intended to be limiting.

### Non-limiting geometric parameter examples

In some embodiments, the number of ridges 136 on a given nodule face 134 is selected based on nodule size, desired channel density, and moldability considerations. By way of non-limiting example, nodules having an outer diameter on the order of about 9.5 mm may include about four to about six ridges, while nodules having an outer diameter on the order of about 6 mm may include about three to about four ridges. In other embodiments, fewer or more ridges may be used.

In some embodiments, ridges 136 extend substantially across a full lateral width of the nodule face 134 (e.g., spanning laterally across the face), thereby providing channel-like grooves 138 that extend laterally across the face. In other embodiments, ridges 136 are segmented or discontinuous, thereby defining discrete ridge “islands” separated by grooves 138.

In some embodiments, ridge pitch (ridge-to-ridge spacing), ridge height, and ridge width are selected based on material compliance and intended scrubbing conditions. For example, ridge pitch may be selected such that the grooves 138 remain open (i.e., not fully collapsed) over a selected range of compression during use, thereby maintaining liquid pathways during scrubbing. In some embodiments, ridge height is selected such that ridge peaks provide initial contact and grooves 138 provide liquid transport regions.

In some embodiments, the nodule face 134 has an overall macro-curvature (in addition to the ridge/groove micro-geometry). For example, the nodule face 134 may be formed to approximate a curvature corresponding to an outer diameter of a cylindrical brush, and/or may be formed with a compound curvature. The macro-curvature can be selected to influence contact area distribution and can be implemented via corresponding cavity shaping in the mold tray 200.

The foregoing nodule-face geometries are provided by way of example.

Additional ridge/groove geometries, patterns, and parameter selections will be apparent to those skilled in the art in view of this disclosure. The disclosed manufacturing approach provides a platform to implement such geometries by machining cavity face surface geometry 214 and molding nodules face-down to replicate the machined cavity features onto the nodule face region 222.

### Wet scrubbing interface and contact behavior

During wet scrubbing, a nodule 130 may be brought into contact with a substrate 10 such that at least a portion of the nodule face 134 engages a substrate surface 12. In typical operation, the brush and the substrate move relative to one another (for example, due to rotation of the brush and/or rotation or translation of the substrate). Cleaning liquid may be supplied to the interface to wet the substrate surface 12 and to transport dislodged contaminants.

The mechanical engagement between the nodule 130 and the substrate surface 12 may be characterized by one or more contact regions 32. A contact region 32 may be formed by direct contact between ridge peaks (e.g., ridges 136) and the substrate surface 12 and/or by contact between other portions of the nodule face 134 and the substrate surface 12. Because materials such as PVA are compliant, the shape and area of the contact region 32 can depend on process parameters including, for example, relative speed, applied normal load, local compression (penetration depth), and local alignment.

In some embodiments, defined nodule-face surface geometry (e.g., ridges 136 and grooves 138) influences how a compliant nodule 130 deforms upon contact. For example, ridge peaks may provide initial contact points that engage the substrate surface 12, while grooves 138 provide intervening regions that can remain at least partially open to facilitate liquid presence and transport at the interface. The distribution of discrete ridge contacts across the nodule face 134 can increase local shear and can promote movement of liquid and dislodged particles away from the immediate contact region 32.

The relative motion at the interface can also impose tangential forces on the nodule 130. Depending on geometry and compliance, tangential loading can bias deformation of the nodule, which in turn can influence whether a localized contact gap 30 forms at a portion of the nodule perimeter or nodule face. Edge-treatment features (e.g., edge treatment 140) and ridge/groove geometry may be selected to reduce formation of such localized gaps, as described further below.

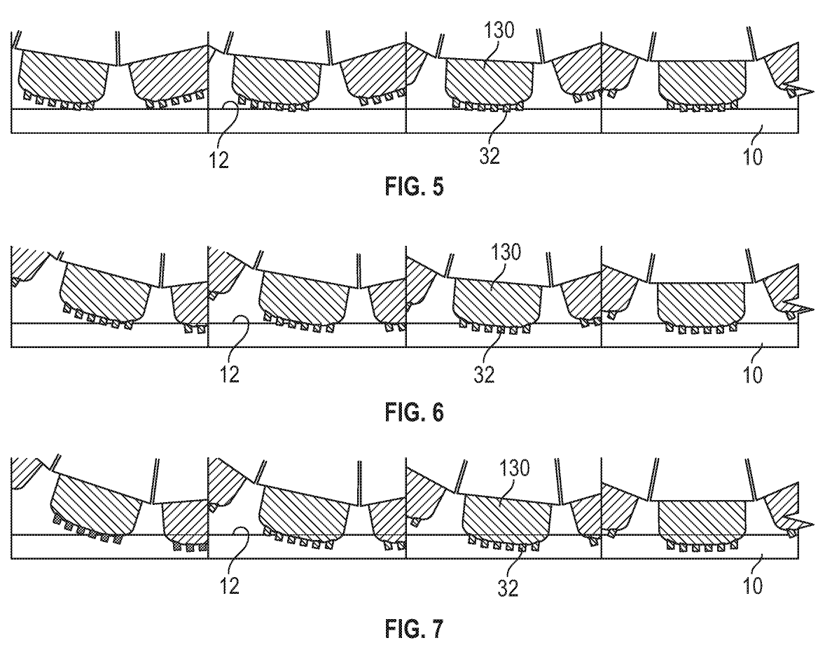

### Contact distribution under differing offsets / compressions (FIGS. 5–7)

FIGS. 5–7 illustrate schematic examples of how contact distribution can change as a function of an offset parameter. As used herein, “offset” refers to a relative displacement between the brush and the substrate that changes the extent of nodule compression against the substrate surface 12 and/or changes local engagement among a population of nodules 130. In many cleaning tools, such an offset parameter can correspond to a penetration depth or compression setpoint established by positioning of a brush axis relative to a substrate plane; other implementations are also contemplated.

In the example of FIG. 5, nodules 130 engage the substrate 10 at a first example offset (e.g., 0.25 mm), which results in a contact region 32 for at least one nodule. In the example of FIG. 6, nodules 130 engage the substrate 10 at a second example offset (e.g., 1.00 mm). In the example of FIG. 7, nodules 130 engage the substrate 10 at a third example offset (e.g., 1.75 mm). These figures are illustrative and not limiting; the depicted offsets and contact behaviors depend on the selected nodule geometry, material properties, and tool conditions.

In some embodiments, ridge/groove surface geometry on a nodule face 134 is selected such that grooves 138 remain at least partially open over a selected range of offsets and compressions. Maintaining open grooves can provide distributed pathways for liquid transport and can reduce the likelihood that a continuous liquid film will fully separate the nodule from the substrate surface 12 over the entire nodule face.

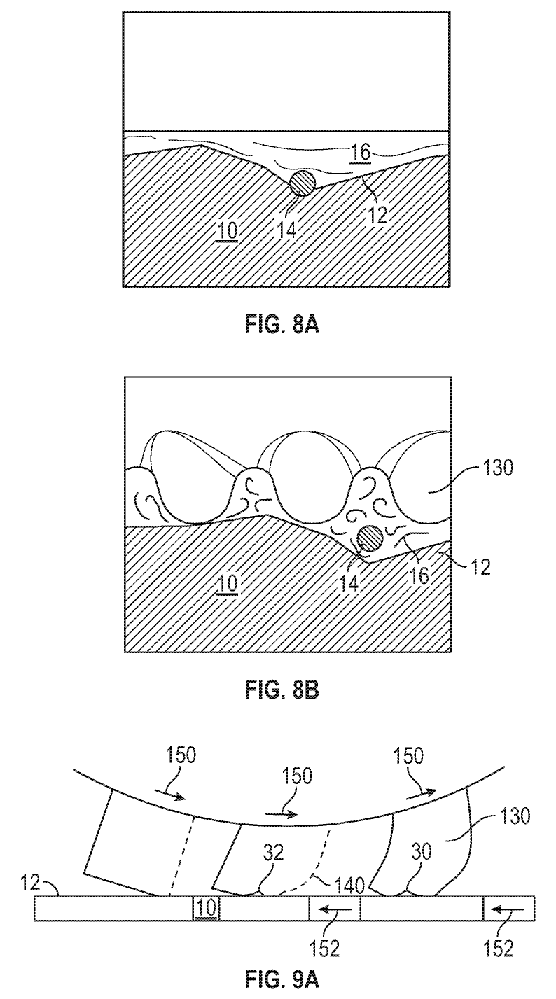

### Fluid film behavior and particle transport (FIGS. 8A–8B)

FIGS. 8A and 8B illustrate simplified schematics of fluid 16 and particle/contaminant 14 behavior at a wet cleaning interface adjacent a substrate surface 12. FIG. 8A illustrates a baseline case in which a particle 14 is present at or near a substrate surface 12 and is acted upon by flow in the fluid 16. Under some process conditions, such flow can transport dislodged particles along the substrate surface and can contribute to redeposition if not efficiently flushed away from the interface.

FIG. 8B illustrates a case in which one or more nodules 130 engage a substrate 10 and the fluid 16 is present at the interface. In some embodiments, the defined nodule-face surface geometry (e.g., ridges 136 and grooves 138) influences local fluid movement. For example, grooves 138 can define channel-like regions that provide preferential paths for liquid to enter and exit the contact region 32 as the nodule moves relative to the substrate. In some embodiments, such channel-like regions facilitate transport of particles 14 away from the immediate contact interface.

Without being bound by theory, in some implementations the presence of ridges and grooves can disrupt formation of a spatially uniform laminar liquid film at the interface by providing distributed drainage paths and multiple discrete contact features. Stated differently, the ridged geometry can reduce the likelihood that the nodule will ride entirely on a liquid film (sometimes described in the art as a fluid-lift or hydroplaning-like condition) under wet, high-speed conditions. In some embodiments, ridge peaks maintain mechanical engagement while grooves provide liquid pathways, thereby improving interface stability under wet scrubbing conditions.

In some embodiments, ridge/groove geometry is selected to influence a directionality of liquid transport, for example by selecting ridge orientation relative to a direction of relative motion. Such directionality may be used to promote flushing of the interface and movement of contaminants away from the substrate surface 12 and toward a bulk-flow region. Additional liquid delivery and distribution structures are described elsewhere in this specification.

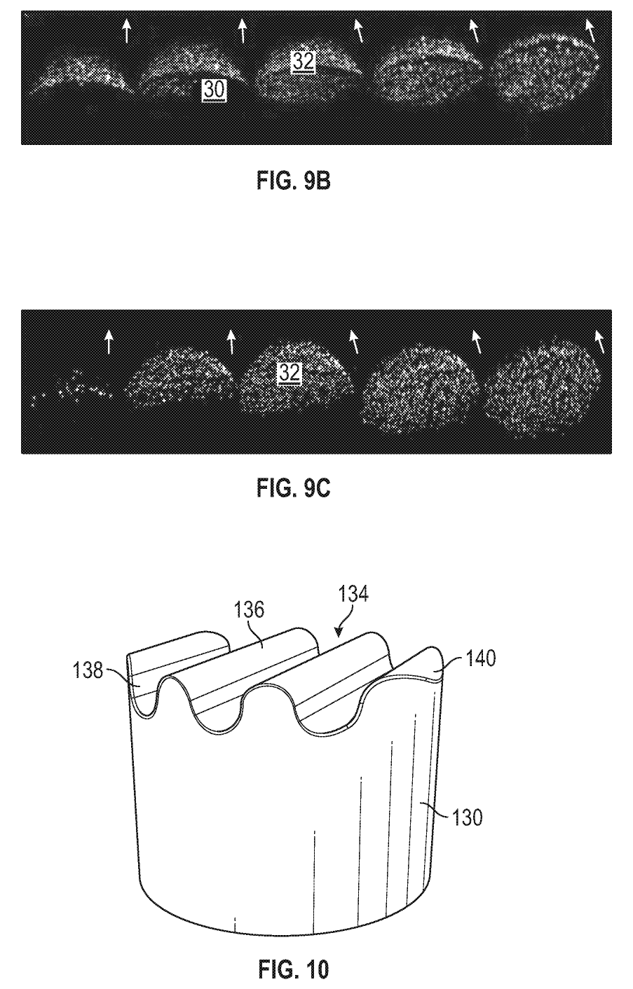

### Edge treatment and contact gap mitigation (FIGS. 9A–9C)

FIGS. 9A–9C illustrate example contact behaviors associated with a standard nodule and an edge-treated nodule. FIG. 9A schematically illustrates a nodule 130 contacting a substrate 10 at a substrate surface 12 and experiencing tangential loading due to relative motion between the brush and the substrate (for example, in the directions indicated by arrows (150) and (152)). Under such loading, a localized gap 30 may form at a portion of the nodule perimeter (sometimes described as a crescent-shaped gap) and a contact region 32 may be biased toward a portion of the nodule face. In some embodiments, an edge treatment 140 at the perimeter of the nodule face is configured to reduce the likelihood and/or size of such a localized gap 30 and to promote a more continuous or more uniformly distributed contact region 32.

FIG. 9B illustrates an example contact area image for a standard nodule. In the example, the contact region 32 is shown along with an example gap 30. FIG. 9C illustrates an example contact area image for an edge-treated nodule. In the example, the contact region 32 is more continuous and/or more uniformly distributed relative to the standard-nodule example. These images are provided as illustrative examples; contact distributions may vary with tool conditions, materials, and geometry.

In some embodiments, the edge treatment 140 is implemented as a radius, fillet, chamfer, bevel, or blended transition between the nodule face and an adjacent perimeter region. In some embodiments, the edge treatment 140 is formed integrally during molding (e.g., via a corresponding cavity feature in cavity face surface geometry 214) such that the perimeter transition is repeatable from nodule to nodule. In some embodiments, edge treatment 140 is applied to a nodule face that also includes ridges 136 and grooves 138, thereby combining perimeter-gap mitigation with ridge-based interface behavior.

Without being bound by theory, reducing localized gaps can improve cleaning by reducing regions of reduced engagement and by reducing regions where contaminants can remain trapped under a lifted portion of the nodule. In some embodiments, improved contact distribution reduces localized nonuniformity and supports more repeatable cleaning results across a substrate.

### Method aspects: wet scrubbing using textured nodules

In another aspect, the disclosure may be implemented as a method of wet cleaning a substrate using a brush having textured nodules. A method may include positioning a brush assembly relative to a substrate 10 and supplying a cleaning liquid to wet a substrate surface 12. The method may further include moving the brush and the substrate relative to one another to cause a plurality of nodules 130 to contact the substrate surface 12.

In some embodiments, the method includes controlling an offset (e.g., a penetration depth/compression setpoint) such that at least a portion of one or more nodule faces 134 compress against the substrate surface 12 to establish contact regions 32. In some embodiments, the method includes maintaining or varying the offset during scrubbing to tune contact distribution, for example to accommodate substrate bow, tool tolerances, or process recipes.

In some embodiments, the method includes using nodules 130 having ridges 136 and grooves 138 at the nodule face 134. In some embodiments, the ridges provide discrete contact features that increase local shear at the interface and the grooves provide pathways for liquid to flow and for dislodged contaminants to egress. In some embodiments, the method includes using nodules having edge treatment 140 to reduce localized gaps during scrubbing.

The foregoing interface descriptions are provided by way of example. Other contact behaviors and fluid/particle transport behaviors are also contemplated, including embodiments in which nodule geometry, edge treatment, and liquid delivery arrangements are selected together to provide desired cleaning performance under selected wet operating conditions.

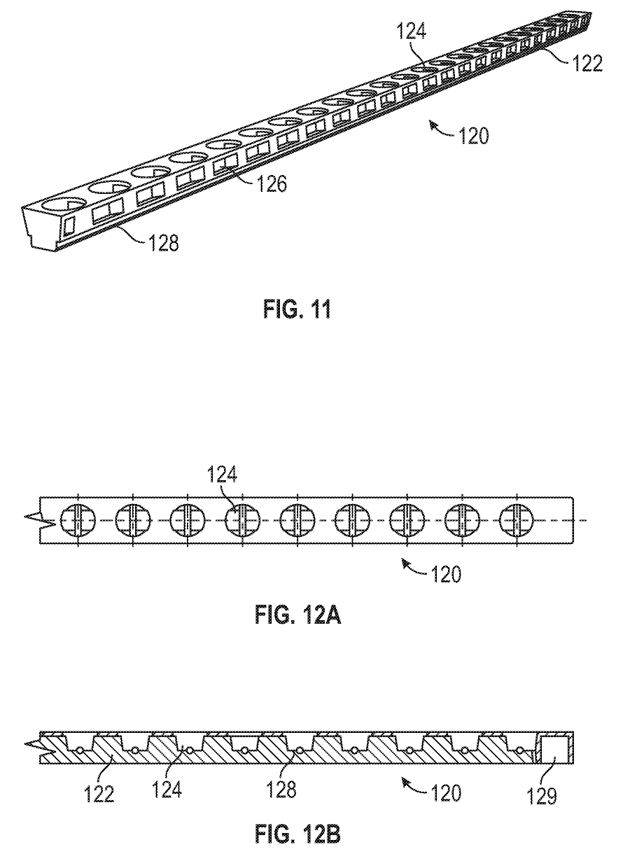

### Modular rail module structure (FIGS. 11–12B)

In some embodiments, a brush assembly is implemented using a modular construction in which a plurality of nodules 130 are carried by one or more modules that are mounted to, or around, a brush core 110. Such modularity can facilitate manufacturing, servicing, and replacement of portions of the brush without requiring replacement of the entire brush assembly. Modularity can also facilitate implementation of different nodule geometries or distributions in different regions of a brush.

Referring to FIG. 11, an example module may be implemented as a rail module 120. The rail module 120 may include a rail body 122 extending along a longitudinal direction. The rail body 122 may define a plurality of nodule receptacles 124. Each nodule receptacle 124 may be sized and shaped to receive and retain a corresponding nodule 130. In the illustrated example, the nodule receptacles 124 are arranged along a length of the rail body 122 and are spaced at a pitch selected for an intended nodule distribution.

The rail body 122 may further define one or more side openings 126. In some embodiments, side openings 126 reduce weight, provide access for liquid flow or drainage, and/or facilitate molding or machining of the rail body 122. In some embodiments, side openings 126 provide access for cleaning or flushing operations during use or servicing.

In some embodiments, the rail body 122 defines one or more openings, ports, or passageways 128. As depicted in FIGS. 11 and 12B, a plurality of openings 128 may be distributed along the rail body 122. In some embodiments, the openings 128 provide fluid communication between an internal region of the rail body 122 and an external region near the nodules 130. In other embodiments, the openings 128 serve as drain holes, vent holes, weight-reduction features, or mounting/registration features. The particular function of openings 128 may vary by implementation, and the drawings are illustrative and not limiting.

Referring to FIG. 12A, the rail module 120 may be viewed from above to illustrate example nodule receptacle positions 124 along the rail body. Referring to FIG. 12B, the rail module 120 may include an end feature 129. In some embodiments, the end feature 129 is configured as an end wall, end plug, stop feature, or alignment feature. In some embodiments, the end feature 129 closes or partially closes an internal region of the rail body 122, for example to define a boundary for liquid distribution or to provide a mounting interface.

The rail body 122 may be formed from a material selected for mechanical rigidity, dimensional stability, and chemical compatibility with the intended wet cleaning environment. Non-limiting examples include engineering polymers, metals, composites, and combinations thereof. In some embodiments, the rail body 122 is substantially non-porous (non-permeable) relative to the nodule material (e.g., PVA), such that liquid supplied to an interior region is preferentially directed toward defined openings or toward the nodule interface rather than permeating through the rail body.

A nodule 130 may be retained in a receptacle 124 using any of a variety of mechanisms. Non-limiting examples include interference fits, snap-fit features, adhesive bonding, thermal bonding, overmolding, insert molding, or combinations thereof. In some embodiments, nodules 130 are formed as discrete elements and then assembled into the rail module 120. In other embodiments, nodules 130 are formed integrally with a support portion that is later attached to the rail body 122.

### Brush assembly incorporating rail modules (FIG. 13)

Referring to FIG. 13, an example brush assembly 100 may include a brush core 110 and one or more rail modules 120 mounted to the core 110. The core 110 may provide structural support and may define a rotational axis for the brush assembly 100. In some embodiments, the core 110 is configured to couple to an end fitting 112 (e.g., a hub, shaft coupling, or bearing interface) that permits rotation and/or mounting in a cleaning tool.

The rail modules 120 may be arranged around an outer circumference of the core 110 such that nodules 130 extend radially outward to define an effective brush outer surface. In the illustrated example, multiple rail modules 120 are arranged in parallel along the core 110 to form longitudinal rows of nodules 130. In other embodiments, rail modules may be arranged in a helical pattern, staggered pattern, or other arrangement to tune contact distribution and liquid transport during scrubbing.

In some embodiments, different rail modules 120 may carry nodules 130 having different nodule-face surface geometries (e.g., different ridge/groove patterns) and/or different nodule heights. For example, a first rail module may carry nodules optimized for a first substrate type or process region, while a second rail module may carry nodules optimized for a different region (e.g., edge region). Such region-specific tuning can be implemented by selecting different cavity face surface geometries 214 in the mold tray 200 during nodule manufacturing.

The rail modules 120 may be attached to the core 110 using any suitable mechanism. Non-limiting examples include mechanical fasteners, clamp features, adhesive bonding, dovetail or tongue-and-groove interfaces, and/or keyed interfaces that establish angular position. In some embodiments, attachment mechanisms permit rail modules to be removed and replaced individually for servicing, refurbishment, or reconfiguration.

### Liquid delivery and distribution (non-limiting examples)

In some embodiments, a cleaning liquid is supplied to the brush assembly 100 during use. Liquid supply may include, by way of non-limiting example, deionized water and/or one or more chemical cleaning compositions. Liquid may be delivered by external nozzles, by distribution through the brush assembly, or by combinations thereof.

In some embodiments, the core 110 defines one or more internal passages for liquid distribution. For example, the core 110 may be hollow, may define an axial bore, and/or may define one or more radial openings that distribute liquid toward the rail modules 120. In some embodiments, liquid is supplied under pressure and/or due to centrifugal effects as the core rotates. In other embodiments, liquid delivery is gravity-fed, pumped, or otherwise supplied.

In some embodiments, the rail modules 120 cooperate with liquid delivered from the core 110. For example, a rail body 122 may define an internal region that receives liquid from the core 110, and the openings 128 may provide fluid communication between that internal region and an external region proximate the nodules 130 and/or the substrate interface. In some embodiments, liquid delivered through openings 128 is directed to wet the interface between nodule faces 134 and the substrate surface 12, and to flush dislodged contaminants away from contact regions 32.

In some embodiments, structural arrangements are selected to encourage a substantial portion of supplied liquid to exit in proximity to, and/or through, the nodules 130. For example, the rail body 122 and/or other housing structures may be substantially non-permeable, and liquid may be directed toward receptacles 124 and/or toward regions behind nodules 130 such that the liquid preferentially travels toward the nodule faces 134. In some embodiments, such arrangements improve liquid usage efficiency by reducing undesired liquid loss through bulk porous material and/or by promoting delivery of fresh liquid at the interface where scrubbing occurs.

In some embodiments, liquid is delivered through a porous nodule body such that the liquid exits through the nodule face 134. In other embodiments, liquid is delivered adjacent the nodule face 134 without necessarily passing through the full nodule body. The term “through” as used in this context may refer to exiting from a region behind the nodule face and/or exiting from a porous structure at or near the nodule face; particular implementations may vary.

In some embodiments, liquid delivery and surface geometry are selected together. For example, ridges 136 and grooves 138 on the nodule face 134 may cooperate with delivered liquid by providing pathways for liquid distribution and contaminant egress across the face. As another example, ridge orientation may be selected to bias liquid transport in a desired direction relative to brush rotation, and edge treatment 140 may reduce localized gaps that could otherwise trap liquid and contaminants.

### Method aspects: assembly and use of modular brush systems

In another aspect, the disclosure may be implemented as a method of assembling a brush for wet cleaning. A method may include providing a core 110 and providing one or more rail modules 120 carrying nodules 130. The rail modules 120 may be attached to the core 110 in a selected angular arrangement around the core. In some embodiments, an end fitting 112 is coupled to the core 110 to permit mounting and rotation in a cleaning tool.

In some embodiments, the method further includes supplying cleaning liquid to the brush assembly 100 during operation. The liquid may be supplied through the core 110 and distributed to rail modules 120 and/or to regions proximate the nodules 130. In some embodiments, the method includes directing liquid through openings 128 to wet and flush the brush/substrate interface.

In some embodiments, the method includes configuring rail modules 120 and/or nodules 130 to tailor contact and flushing behavior. For example, a subset of rail modules may carry nodules having a first ridge/groove geometry, while another subset carries nodules having a second geometry. In some embodiments, rail modules are selected and arranged to define different functional zones along an axial length of the brush and/or around a circumference of the brush.

The foregoing modular brush and liquid delivery descriptions are provided by way of example. Other modular configurations, attachment mechanisms, and liquid delivery arrangements are contemplated. The disclosed manufacturing approach can provide a platform for producing nodules having repeatable surface geometry for integration into such modular brush systems.

### Combined system configurations

As described above, the disclosed mold tray approach (FIG. 14) provides an enabling backbone for producing nodules 130 having repeatable nodule-face surface geometries, including ridges 136 and grooves 138 and, in some embodiments, an edge treatment 140. The disclosed brush system may then integrate such nodules into a modular brush architecture (FIGS. 11–13) and into a wet scrubbing interface context (FIGS. 5–9).

In some embodiments, the brush system is configured as a combined set of design “levers” that can be selected together for a target process. Non-limiting examples of such levers include: (i) the nodule-face surface geometry (ridge/groove pattern, ridge profile, and ridge orientation); (ii) the perimeter edge treatment 140; (iii) the nodule distribution and nodule height across a brush; (iv) modular rail selection and rail arrangement around a core; and (v) liquid delivery and distribution arrangements that wet and flush the brush/substrate interface.

In some embodiments, the modularity of rail modules 120 allows region-specific tuning. For example, a first set of rail modules 120 may carry nodules having a first ridge/groove geometry optimized for a first cleaning objective (e.g., high flushing), while a second set of rail modules may carry nodules having a second geometry optimized for a different objective (e.g., improved edge contact behavior). Because the nodule-face surface geometry is formed during molding using a cavity face surface geometry 214, different nodule geometries may be produced by changing the cavity face surface geometry (e.g., by changing inserts or changing a tray), and then assembling the resulting nodules into the desired rails.

In some embodiments, the disclosed manufacturing approach enables rapid iteration and process matching. For example, a development program may evaluate multiple candidate ridge patterns (linear, angled, sinusoidal, chevron, etc.) and multiple edge-treatment geometries by machining different cavity face surface geometries 214 and molding corresponding nodules. Such candidate nodules can then be assembled into rail modules and evaluated under controlled wet cleaning conditions.

### Directed-flow and purging arrangements

In some embodiments, the brush system is configured to promote delivery of cleaning liquid proximate the nodules and to reduce undesired liquid loss through bulk porous material that does not contribute to cleaning at the interface. For example, in some embodiments, one or more structural components (e.g., a rail body 122 and/or an associated housing portion) are substantially non-porous, and liquid supplied to an interior region is preferentially directed toward the nodules and/or the nodule faces. In some embodiments, a substantial portion of supplied liquid exits at or near the nodule faces 134.

In some embodiments, one or more flow-control features are provided to control and/or balance distribution of cleaning liquid within the brush assembly. Non-limiting examples of such flow-control features include one or more baffles, valves, restrictions, channels, and/or porous inserts, alone or in combination, configured to reduce bypass flow and to promote delivery of cleaning liquid toward desired nodule locations and/or toward nodule faces.

In some embodiments, the brush assembly is configured such that at least about 50%, at least about 70%, at least about 90%, or substantially all of the delivered cleaning liquid exits at or through the nodule faces. In other embodiments, the delivered cleaning liquid exits the brush predominantly through the nodule faces, with some portion exiting through other leakage paths depending on construction and operating conditions.

In some embodiments, such directed-flow arrangements cooperate with ridge/groove surface geometry at the nodule faces. For example, grooves 138 can provide distributed pathways for liquid to enter and exit contact regions, and ridges 136 can provide discrete engagement points. In some embodiments, the combination of directed liquid supply and defined face geometry improves flushing and reduces contaminant retention within the brush.

In some embodiments, a water-flow analysis (as reported in internal test materials provided with this disclosure) suggested that certain conventional brushes may lose a substantial portion of supplied liquid through a porous brush body rather than through nodules. In some implementations, directing liquid preferentially through nodules and/or nodule faces can reduce such losses. The foregoing is provided as a non-limiting example; particular results depend on brush construction and process conditions.

### Examples of test methods and results

The following examples are provided to illustrate certain non-limiting test methods and results associated with representative embodiments. The examples are not intended to be limiting as to structure, process conditions, or outcomes. Unless otherwise stated, test parameters and measurement protocols may vary by tool and facility. Results can vary with wafer type, chemistry, tool configuration, and process settings.

In several example tests described in the provided disclosures, particle or defect counts were measured before and after a scrubbing step. In such cases, a “pre” value can refer to a measured defect/particle count before scrubbing, a “post” value can refer to a measured defect/particle count after scrubbing, and an “adder” value can refer to a change (e.g., post minus pre) associated with the scrubbing process. In some instances, negative adder values indicate a reduction in measured defects/particles from pre to post.

Example 1 (Oxide wafer particle count example; reduced flow). In one example disclosed in the provided materials, an oxide wafer test was performed using a 12-row nodule design. The example reported a water flow rate of about 1.25 L/min to a brush box for a brush according to embodiments of this disclosure, as compared to about 2.0 L/min for one or more comparator brush configurations. In the same example, the brush according to embodiments was reported to produce fewer particles while using less water. The disclosed materials further reported that a reduction in flow from 2.0 L/min to 1.25 L/min corresponds to a reduction of 0.75 L/min, equal to 1,080 L per tool per day (assuming 24-hour operation) and 32,400 L per tool per 30-day month.

Example 1 (continued). In the same disclosed example, a table of particle counts included pre- and post-scrub values for two comparator configurations (each at 2.0 L/min) and for the brush according to embodiments (at 1.25 L/min). The table reported pre values of 60,738 and 55,020 for the comparator configurations and 64,801 for the brush according to embodiments, and post values of 99 and 152 for the comparator configurations and 65 for the brush according to embodiments. The same disclosed materials stated that the brush according to embodiments was run at a reduced scrubbing condition (reported as 25% less scrubbing) and produced 34.3% and 57.3% fewer particles than the comparator configurations, respectively, while using 37.5% less water. The foregoing is reproduced as a non-limiting example as reported in the disclosed materials.

Example 2 (MO pattern wafer recessing). In a disclosed MO pattern wafer recessing comparison, a chart compared a first comparator brush to a brush according to embodiments of this disclosure for two structures (Structure 1 and Structure 2) using a recess metric (AU, as labeled in the disclosed materials). The chart reported recess values of 2.79 (Structure 1) and 3.40 (Structure 2) for the comparator brush, and 1.34 (Structure 1) and 2.06 (Structure 2) for the brush according to embodiments.

Example 3 (Bare wafer test – 19 nm). In a disclosed bare wafer test labeled “Bare Wafer Test (19 nm),” a chart of defect adders (bare Si, 19 nm) compared a baseline process-of-record (POR) condition to a brush according to embodiments of this disclosure. The chart included representative values labeled 408 for the POR condition and 396 for the brush according to embodiments. The chart further illustrated distributions for each condition.

Example 4 (Break-in time and bare wafer test – 80 nm). In a disclosed test labeled “Break-in Time & Bare Wafer Test (80 nm),” a plot compared a comparator brush to a brush according to embodiments of this disclosure across a sequence of wafers, showing defect counts (DSA, as labeled in the disclosed materials) versus number of wafers run. The disclosed plot showed reduced defect counts for the brush according to embodiments relative to the comparator across multiple measurement points. A second chart labeled “Bare-Si BTW” illustrated defect count distributions for the brush according to embodiments and for an additional comparator condition.

Example 5 (Bare wafer test – 37 nm). In a disclosed bare wafer test labeled “Bare Wafer Test (37 nm),” a bar chart compared adder values for three brushes: a first comparator brush (adder 63), a brush according to embodiments of this disclosure (adder 44), and a second comparator brush (adder 66). The disclosed materials further included a table reporting pre and post values and the derived adder for each: first comparator (pre 207, post 80, adder 63), brush according to embodiments (pre 13, post 50, adder 44), and second comparator (pre 80, post 85, adder 66).

Example 6 (Oxide wafer test – 50 nm; high/low chemical flow). In a disclosed oxide wafer test labeled “Oxide Wafer Test (50 nm),” a chart compared adders for a brush according to embodiments of this disclosure and a baseline POR condition under two chemical-flow conditions labeled “High Chem Flow” and “Low Chem Flow.” The disclosed materials reported the following pre/post/adder values: for the brush according to embodiments under High Chem Flow, pre 486, post 99, adder -387; for POR under High Chem Flow, pre 496, post 903, adder 407; for the brush according to embodiments under Low Chem Flow, pre 334, post 126, adder -208; and for POR under Low Chem Flow, pre 262, post 281, adder 19.

The foregoing examples are provided to illustrate non-limiting results and do not constitute a requirement that any embodiment achieve any particular performance metric. Embodiments may be implemented with different nodule geometries, module constructions, and liquid delivery arrangements, and may be tuned for different substrates and process objectives.

### Definitions and interpretation

The terminology used herein is for the purpose of describing particular embodiments only and is not intended to be limiting. Unless otherwise defined, technical and scientific terms used herein have the meaning commonly understood by persons of ordinary skill in the art in view of this disclosure.

As used herein, the terms “comprise,” “comprises,” “comprising,” “include,” “includes,” and “including” are open-ended and do not exclude additional elements, components, integers, steps, or features not expressly recited. The term “consist of” is closed-ended. The term “consist essentially of” is intended to be partially closed-ended, allowing additional elements or steps that do not materially affect the basic and novel characteristics of the claimed subject matter.

The singular forms “a,” “an,” and “the” include plural referents unless the context clearly indicates otherwise. As used herein, “or” is inclusive unless the context clearly indicates otherwise. Unless otherwise indicated, “and/or” is intended to mean any one or more of the associated listed items, individually or in combination.

Relative terms such as “generally,” “substantially,” “about,” “approximately,” and the like are intended to account for normal manufacturing tolerances, measurement uncertainty, material variability (including swell/shrink for porous polymeric materials), and implementation-dependent variation. Unless otherwise stated, the term “about” does not require any particular numerical tolerance and is intended to be interpreted in a manner consistent with the context and with the understanding of persons of ordinary skill in the art.

The phrase “configured to” (and similar phrases such as “arranged to” or “adapted to”) is used to describe structures or features that are capable of performing the recited function, and does not require that such function be performed in all modes of operation or under all conditions.

The terms “coupled,” “connected,” and “in communication with” may refer to direct coupling/connection/communication or indirect coupling/connection/communication through one or more intermediate elements, unless expressly stated otherwise.

As used herein in connection with liquid delivery, the phrase “through a nodule” or “through the nodule face” may refer to liquid traveling through a porous structure of a nodule, liquid traveling through one or more defined openings or passages proximate the nodule, and/or liquid exiting at or near the nodule face region. Particular flow paths may vary by implementation.

The terms “non-porous,” “non-permeable,” and “substantially non-permeable,” when used to describe a structural component (e.g., a rail body or housing), are intended to be relative terms in the context of the disclosed systems. For example, a rail body may be described as substantially non-permeable relative to a porous PVA nodule material if the rail body does not permit bulk fluid transport through its thickness under intended operating conditions to the same extent as the porous nodule material.

As used herein, a “nodule” refers generally to a protruding scrubbing element configured to engage a substrate during a cleaning operation. A “nodule face” refers to a portion of a nodule intended to contact a substrate during scrubbing. A nodule face may be planar, curved, or non-planar, and may include surface geometry as described herein.

As used herein, “ridges” and “grooves” refer to alternating raised and recessed surface features (respectively) on a nodule face. For convenience, the disclosed surface geometry is described using the terms “ridges” and “grooves”; however, in some embodiments functionally similar surface geometry may be implemented using one or more recessed channels, one or more raised ribs, or combinations thereof, and the disclosure is not limited to any particular sign convention for protrusions versus recesses.

As used herein, an “edge treatment” refers to a perimeter transition at a nodule face, for example between a nodule face and an adjacent perimeter region or sidewall. Non-limiting examples include a radius, fillet, chamfer, bevel, or blended transition. Unless expressly stated, an edge treatment is not limited to a particular geometry.

As used herein, “face-down molding” refers to molding in which a nodule face region is formed against a cavity face surface geometry of a mold cavity, such that the cavity face surface geometry defines (as a negative) a corresponding surface geometry on the molded nodule face region.

As used herein, “cavity face surface geometry” refers to a surface geometry defined on a mold surface that contacts and forms a nodule face region during molding. Such cavity face surface geometry may include, without limitation, ridge-forming and valley-forming features and/or perimeter transition features to form an edge treatment.

As used herein, “offset” refers to a relative displacement between a brush and a substrate that changes an extent of engagement, compression, or penetration of one or more nodules against a substrate surface. An offset may correspond to a tool setpoint, a penetration depth, a compression amount, or other alignment parameter, depending on implementation.

As used herein, “module” refers to a component or subassembly configured to carry or position one or more nodules and to be assembled into a brush. A “rail module” refers to a module having an elongated form factor carrying a plurality of nodules along a length of the module. The disclosure is not limited to any particular module geometry.

Unless the context clearly requires otherwise, features described in connection with one embodiment may be combined with features described in connection with other embodiments. If a method is described, the recited steps may be performed in a different order and/or with additional or fewer steps unless the context clearly requires a particular order.

When numerical ranges are disclosed, such ranges are intended to include the endpoints and all subranges therebetween, unless otherwise indicated. When multiple embodiments are described, the disclosure is intended to support claims directed to each described embodiment, as well as combinations of described embodiments, to the extent consistent with this disclosure.

The foregoing description of the present disclosure has been presented for the purpose of illustration and description. It is not intended to be exhaustive or to limit the disclosure to the precise form disclosed. Many modifications and variations are possible in light of the above teachings. It is intended that the scope of the present disclosure not be limited by this detailed description, but by the claims and the equivalents to the claims appended hereto.

1. A cylindrical brush for wet cleaning of a substrate, comprising:
a central core configured for rotational movement about a longitudinal axis;
a plurality of polyvinyl alcohol (PVA) nodules disposed on an outer surface of the central core, each nodule having a nodule face configured to contact the substrate during cleaning;
wherein the nodule face includes a ridged surface structure comprising one or more ridges;
and wherein the ridged surface structure is configured to redistribute liquid at a brush/substrate interface to enhance particle removal and to displace liquid to reduce hydroplaning and maintain contact between the nodules and the substrate under wet conditions.

2. The cylindrical brush of claim 1, wherein the ridged surface structure comprises a plurality of laterally extending ridges spanning a width of the nodule face.

3. The cylindrical brush of claim 1, wherein the ridged surface structure comprises a sinusoidal wave profile on the nodule face.

4. The cylindrical brush of claim 1, wherein the ridged surface structure comprises straight slats having rounded edges.

5. The cylindrical brush of claim 1, wherein the ridged surface structure comprises between 3 and 6 ridges on the nodule face.

6. The cylindrical brush of claim 1, wherein the ridged surface structure is oriented substantially perpendicular to a direction of relative motion between the nodule face and the substrate during cleaning.

7. The cylindrical brush of claim 1, wherein the ridged surface structure is oriented at a non‑perpendicular angle relative to a direction of relative motion between the nodule face and the substrate during cleaning to impart a lateral transport component to liquid and particles.

8. The cylindrical brush of claim 1, wherein at least one of (i) a perimeter of the nodule face and (ii) an edge of a ridge includes an edge treatment comprising a radius or chamfer configured to reduce a crescent-shaped contact gap during cleaning.

9. The cylindrical brush of claim 8, wherein the edge treatment comprises a radius between about 0.35 mm and about 0.85 mm.

10. The cylindrical brush of claim 1, further comprising a fluid management system configured to direct a cleaning liquid through the nodules toward the nodule faces such that the cleaning liquid exits the brush predominantly through the nodule faces.

11. The cylindrical brush of claim 10, wherein the fluid management system is configured such that, during operation, the cleaning liquid exits the brush substantially exclusively through the nodule faces, and further comprising at least one flow-control feature selected from the group consisting of a baffle, a valve, a restriction, a channel, and a porous insert, the flow-control feature configured to control flow through at least one nodule.

12. The cylindrical brush of claim 10, wherein the fluid management system comprises an axial fluid passage in the core and a plurality of apertures in the core configured to deliver the cleaning liquid radially outward into PVA material.

13. The cylindrical brush of claim 1, wherein the plurality of nodules are arranged in staggered rows along a length of the brush.

14. The cylindrical brush of claim 1, wherein nodules in a first zone of the brush have a first ridge geometry and nodules in a second zone have a different ridge geometry.

15. A method of cleaning a semiconductor wafer, comprising:
rotating a cylindrical brush comprising a core and a plurality of PVA nodules having ridged nodule faces;
contacting the semiconductor wafer with the ridged nodule faces under wet conditions;
delivering a cleaning liquid to the brush; directing the cleaning liquid through the nodules such that the cleaning liquid exits the brush predominantly through the nodule faces; and
moving the brush and the semiconductor wafer relative to one another to scrub the semiconductor wafer while the ridged nodule faces disrupt laminar liquid flow and reduce hydroplaning.

16. The method of claim 15, wherein the ridged nodule faces comprise a plurality of raised ridges separated by a plurality of grooves.

17. The method of claim 15, wherein the ridges extend across a lateral width of each ridged nodule face, and wherein the ridges have a substantially linear profile on the ridged nodule faces.

18. The method of claim 15, wherein the ridges are oriented substantially perpendicular to a direction of relative motion between the ridged nodule faces and the semiconductor wafer at the contact interface.

19. The method of claim 15, wherein delivering the cleaning liquid to the brush comprises supplying the cleaning liquid through an internal passage of the core and distributing the cleaning liquid from the core toward the plurality of PVA nodules.

20. The method of claim 19, wherein causing the cleaning liquid to exit the brush predominantly through the nodule faces comprises causing at least 70% of the delivered cleaning liquid to exit at or through the nodule faces.
